(19) United States
(12) Patent Application Publication
(10) Pub. No.: US 2008/0259698 A1
(43) Pub. Date: Oct. 23, 2008

(54) HIGH SPEED DUAL PORT MEMORY WITHOUT SENSE AMPLIFIER

(75) Inventors: Onur Ozbek, Lynnwood, WA (US); Bert Sullam, Bellevue, WA (US)

Correspondence Address: Stolowitz Ford Cowger, LLP/Cypress, 621 Sw Morrison St., Suite 600, Portland, OR, 97205, US

(73) Assignee: Cypress Semiconductor Corp., San Jose, CA (US)

(21) Appl. No.: 11/967,243

(22) Filed: Dec. 30, 2007

Related U.S. Application Data
(60) Provisional application No. 60/912,399, filed on Apr. 17, 2007.

(51) Int. Cl. G11C 7/00; G11C 8/00

(52) U.S. Cl. 365/189.14; 365/230.05; 365/230.06

(57) ABSTRACT

A system includes at least one word line decoder to select word lines to activate, and a memory cell array having a plurality of memory cell devices to store data received through one or more write bit lines. At least one of the memory cell devices including a memory cell to store data received over one or more write bit lines, and a sensing inversion device coupled to the memory cell and word lines. The sensing inversion device can read data stored by the memory cell and provide the read data to one or more read bit lines when at least one of the word lines is activated for read operations.

### RELATED APPLICATIONS

This application claims the benefit of U.S. Provisional Application No. 60/912,399, filed Apr. 17, 2007, which is incorporated herein by reference.

### TECHNICAL FIELD

This disclosure relates generally to memory devices, and more particularly to memory cell access operations in dual port memory devices.

### BACKGROUND

Many memory devices, such as those including Static Random Access Memory (SRAM), include analog sense amplifiers to detect and amplify data stored in memory cells during read operations. FIG. 1 shows a conventional dual port static random access memory (SRAM) device 100. Referring to FIG. 1, the dual port SRAM device 100 includes an SRAM memory cell 110 coupled to multiple bit line pairs, BL0- B̅L̅0̅ and BL1- B̅L̅1̅. During read operations, the SRAM memory cell 110 provides stored data to at least one of the bit lines BL0, B̅L̅0̅, BL1, and B̅L̅1̅, which is then propagated to analog sense amplifiers 120 for detection and amplification. Since the dual port SRAM device 100 utilizes each bit line BL0, B̅L̅0̅, BL1, and B̅L̅1̅ for both reading and writing operations, in some instances, reading data by the SRAM memory cell 110 can be unreliable, suffering from a phenomenon known as a read disturb. The read disturb phenomenon occurs when data associated with write operations interferes with data being read from the SRAM memory cell 110.

Although the analog sense amplifiers 120 can detect the data stored in SRAM memory cell 110, their inclusion in dual port SRAM device 100 is often costly. For instance, the analog sense amplifiers 120 occupy a large area in the dual port SRAM device 100, which increases both the size and cost of these memory devices. Furthermore, since the sense amplifiers 120 are analog, their operation requires a large amount of current, increasing power consumption of the dual port SRAM device 100.

### SUMMARY

A device comprising a memory cell to store data received over one or more write bit lines, and a sensing inversion device coupled to the memory cell and word lines, the sensing inversion device to read data stored by the memory cell and provide the read data to one or more read bit lines when at least one of the word lines is activated for read operations.

The sensing inversion device is operable to receive the stored data directly from the memory cell, and to generate an output based on the data from the memory cell, and provide the generated output to one or more of the read bit lines. The sensing inversion device includes a synchronous sensing inverter coupled to a pair of synchronous word lines, the synchronous sensing inverter to read data from the memory cell when this pair of the synchronous word lines is activated. The sensing inversion device includes an asynchronous sensing inverter coupled to a pair of asynchronous word lines, the asynchronous sensing inverter to read data from the memory cell when this pair of the asynchronous word lines is activated. The memory cell is a static random access memory cell including a pair of inverters to store the data.

The device including at least one data write driver to provide data to be written to the memory cell over at least one of the write bit lines, the memory cell to store the data provided by the data write driver according to a write enable signal The device including multiple write transistors to enable the data from the data write drivers to propagate to the memory cell when activated by the write enable signal.

A method comprising receiving data stored in a memory cell at a sensing inversion device, receiving at least one activation signal corresponding to word lines coupled to the digital sensing device, and reading the data from the memory cell responsive to the activation of the word lines.

The reading of data from the memory cell includes providing the data to one or more read bit lines responsive to the activation of the word lines. The reading of data from the memory cell includes generating a synchronous output based on the data from the memory cell when the synchronous word lines are activated. The reading of data from the memory cell includes generating an asynchronous output based on the data from the memory cell when the asynchronous word lines are activated. The memory cell is a static random access memory cell including a pair of inverters to store the data.

The method includes writing data to the memory cell when a write enable signal is activated. The reading of data from the memory cell and the writing of data to the memory cell are performed over different bit lines

A system comprising, in some embodiments, two word line decoders to select word lines to activate, and a memory cell array having a plurality of memory cell devices to store data received through one or more write bit lines, the memory cell devices including sensing inversion devices to read data stored in the corresponding memory cell devices according to the activation of the selected word lines and provide an output associated with the read data to one or more read bit lines.

At least one of the word line decoders is operable to provide a write enable signal to the memory cell corresponding to the activation of the selected word lines, the write enable signal to indicate whether data is to be written to or read from the memory cell.

The device including a synchronous word line decoder to select the synchronous word lines to activate, at least one of the sensing inversion devices to read data stored in the corresponding memory cells according to the activation of the synchronous word lines. One or more of the sensing inversion devices include synchronous sensing inverters to generate a synchronous output based on data stored in the corresponding memory cells and to provide the synchronous output to one or more synchronous bit lines.

The device including an asynchronous word line decoder to select the asynchronous word lines to activate, at least one of the sensing inversion devices to read data stored in the corresponding memory cells according to the activation of the asynchronous word lines. One or more of the sensing inversion devices include asynchronous sensing inverters to generate an asynchronous output based on data stored in the corresponding memory cells and to provide the asynchronous output to one or more asynchronous bit lines.

### DESCRIPTION OF THE DRAWINGS

The invention may be best understood by reading the disclosure with reference to the drawings.

FIG. 1 shows a conventional dual port static random access memory (SRAM) device.

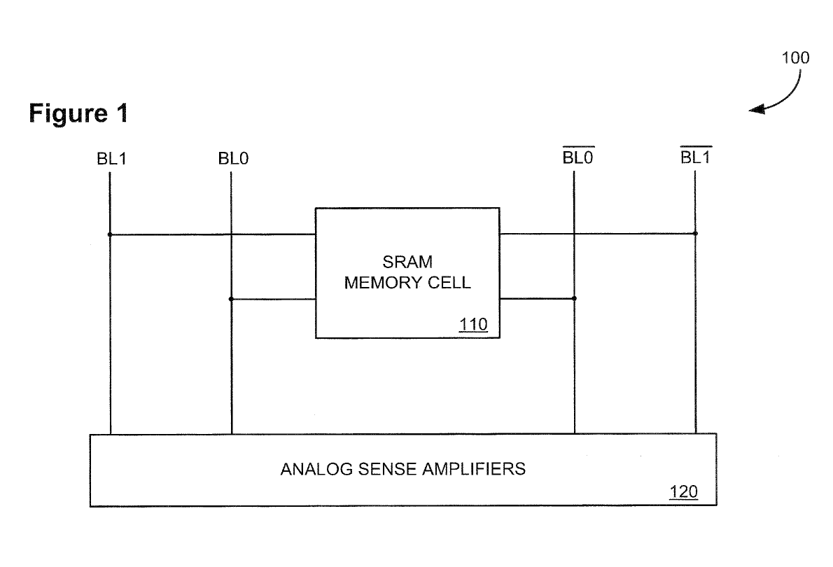

FIG. 2 is a block diagram of a memory system according to embodiments of the invention.

FIG. 3 is a block diagram embodiment of a memory cell device shown in FIG. 2.

FIGS. 4A and 4B are schematic diagrams of embodiments of the digital sensing inverters shown in FIG. 3.

FIG. 5 is an example flowchart of the sensing inversion device is shown in FIG. 3.

### DETAILED DESCRIPTION

A memory system includes at least one memory cell capable of storing data provided during write operations over write bit lines. The memory system further includes a digital sensing device capable of reading data stored by the memory cell and providing the read data to one or more read bit lines. By including distinct read and write paths, the current memory system architecture avoids a common read disturb phenomenon. Furthermore, the utilization of a digital sensing device, as opposed to an analog sense amplifier, allows for reduced system size and current consumption, with a high-speed response during read operations. Embodiments are shown and described below in greater detail.

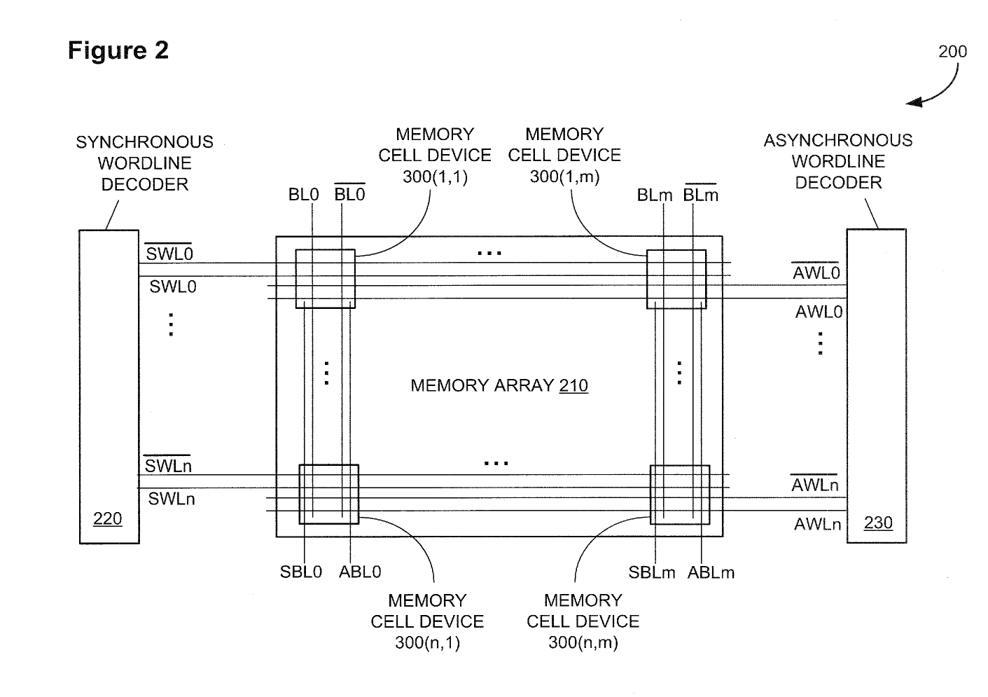

FIG. 2 is a block diagram of a memory system 200 according to embodiments of the invention. Referring to FIG. 2, the memory system 200 includes a memory array 210 having a plurality of memory cell devices 300 to store data. The memory cell devices 300 can be arranged in a row-column format, with a memory cell device 300 residing at the intersection of each row and column. For instance, memory cell device 300(1,1) can reside at the intersection of a first row and a first column, memory cell device 300(n,1) can reside at the intersection of an nth row and the first column, memory cell device 300(1,m) can reside at the intersection of an first row and a mth column, and memory cell device 300(n,m) can reside at the intersection of a nth row and the mth column. Although FIG. 2 shows the memory system 200 having a memory array 210 in a row-column format, in some embodiments, the memory array 210 may have other suitable configurations of memory cell devices 300.

The columns of memory cell devices 300 are coupled to a pair of bit lines BL0- B̅L̅0̅ to BLm- B̅L̅m̅ that can be utilized for writing data to the corresponding memory cell devices 300. For instance, each memory cell device 300 in a first column is coupled to the pair of bit lines BL0- B̅L̅0̅ and receives data to store from the pair of bit lines BL0- B̅L̅0̅ during write operations.

The columns of memory cell devices 300 are coupled to one or more read bit lines utilized for reading data from the memory cell devices 300. For instance, each column of memory cell devices 300 includes at least one synchronous bit line SBL0-SBLm and at least one asynchronous bit line ABL0-ABLm. The memory cell devices 300 can provide stored data to the corresponding synchronous bit line SBL0-SBLm and/or asynchronous bit line ABL0-ABLm during read operations. By reading data from memory cell devices 300 with different bit lines than used to write data to the memory cell devices 300, the memory system 200 can avoid a read disturb phenomenon, where data to be written to the memory cell devices 300 interferes with reading data stored in the memory cell devices 300.

The memory system 200 can include a synchronous word line decoder 220 coupled to rows of memory cell devices 300 through corresponding pairs of synchronous word lines SWL0- S̅W̅L̅0̅ to SWLn- S̅W̅L̅n̅. For instance, each memory cell device 300 in a first row is coupled to the synchronous word line decoder 220 through synchronous word lines SWL0- S̅W̅L̅0̅, while each memory cell device 300 in an nth row is coupled to the synchronous word line decoder 220 through synchronous word lines SWLn- S̅W̅L̅n̅.

The synchronous word line decoder 220 can receive and decode instructions from a memory controller (not shown) and activate one or more of the pairs of synchronous word lines SWL0- S̅W̅L̅0̅ to SWLn- S̅W̅L̅n̅ responsive to the decoded instructions. In some embodiments, the synchronous word line decoder 220 may be a multiplexer that activates one or more of the pairs of synchronous word lines SWL0- S̅W̅L̅0̅ to SWLn- S̅W̅L̅n̅ responsive to instruction input from the memory controller.

The synchronous word line decoder 220 can also identify the type of memory operation to be performed on the memory array 210, i.e., a read or a write operation, and provide an indication of the type of memory operation to at least the memory cell devices 300 corresponding to the activated synchronous word lines SWL0- S̅W̅L̅0̅ to SWLn- S̅W̅L̅n̅. In some embodiments, the synchronous word line decoder 220 selects one or more memory cell devices 300 to perform a memory access operation, for example, a read or a write operation, and activates a write enable signal (not shown) when write operations are to be performed by the memory array 210 and deactivates the write enable signal when synchronous read operations are to be performed by the memory array 210.

The memory system 200 can include an asynchronous word line decoder 230 coupled to the rows of memory cell devices 300 through corresponding pairs of asynchronous word lines AWL0- A̅W̅L̅0̅ to AWLn- A̅W̅L̅n̅. For instance, each memory cell device 300 in a first row is coupled to the asynchronous word line decoder 230 through asynchronous word lines AWL0- A̅W̅L̅0̅, while each memory cell device 300 in an nth row is coupled to the asynchronous word line decoder 230 through asynchronous word lines AWLn- A̅W̅L̅n̅.

The asynchronous word line decoder 230 can receive and decode instructions from a memory controller (not shown) and activate one or more of the pairs of asynchronous word lines AWL0- A̅W̅L̅0̅ to AWLn- A̅W̅L̅n̅ responsive to the decoded instructions. In some embodiments, the asynchronous word line decoder 230 can activate one or more of the pairs of synchronous word lines AWL0- A̅W̅L̅0̅ to AWLn- A̅W̅L̅n̅ responsive to instruction input from the memory controller.

The asynchronous word line decoder 230 can also identify the type of memory operation to be performed on the memory array 210, i.e., a read or a write operation, and provide an indication of the type of memory operation to at least the memory cell devices 300 corresponding to the activated asynchronous word lines AWL0- A̅W̅L̅0̅ to AWLn- A̅W̅L̅n̅. In some embodiments, the asynchronous word line decoder 230 activates a write enable signal (not shown) when write operations are to be performed by the memory array 210 and deactivates the write enable signal when asynchronous read operations are to be performed by the memory array 210.

During read operations, the synchronous word line decoder 220 and/or the asynchronous word line decoder 230 can receive instructions to activate one or more synchronous word lines and/or asynchronous word lines, respectively, and to deactivate the write enable signal. The corresponding memory cell devices 300 provide their stored data to the synchronous bit lines SBL0-SBLm and/or asynchronous bit lines ABL0-ABLm responsive to the activation of the synchronous word lines and/or asynchronous word lines and the deactivation of the write enable signal.

During write operations, the synchronous word line decoder 220 and/or the asynchronous word line decoder 230 can receive instructions to activate the write enable signal corresponding to the row of memory cell devices 300. The memory cell devices 300 can receive and store data from the corresponding bit lines responsive to the write enable signal.

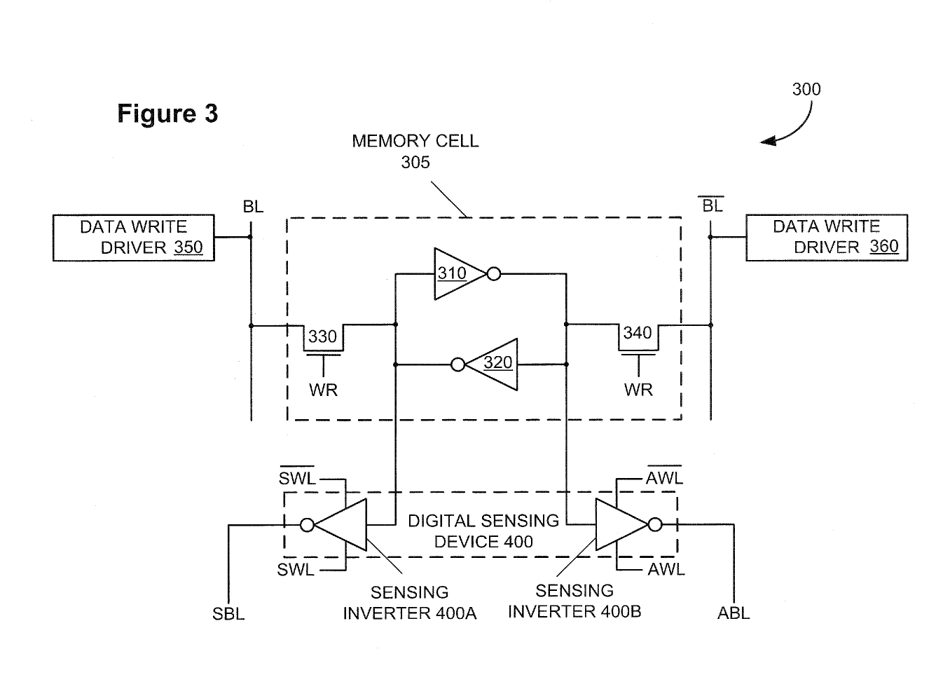

FIG. 3 is a block diagram embodiment of a memory cell device 300 shown in FIG. 2. Referring to FIG. 3, the memory cell device 300 includes a memory cell 305 to store data for the memory system 200. In some embodiments, the memory cell 305 can be a static random access memory (SRAM) cell, for example, in a 6 transistor configuration. The memory cell device 300 writes data to the memory cell 305 through one set of bit lines BL and B̅L̅, and reads data from the memory cell 305 through another set of bit lines SBL and ABL. Since the memory cell device 300 includes separate paths or bit lines to perform read and write operations on the memory cell 305, there is no longer a concern about a read disturb phenomenon that plagues conventional memory devices.

### Data Write Operations

The memory cell 305 can include a pair of inverters 310 and 320 to store data can receive data to store through bit lines BL and B̅L̅. In some embodiments, data write drivers 350 and 360 provide the data the respective bit lines BL and B̅L̅ during data write operations. The data write drivers 350 and 360 can located in the memory system 200, and optionally can be located internally or externally to the memory cell device 300.

The memory cell 305 includes a pair of write transistors 330 and 340 that control when data from the bit lines BL and B̅L̅ is allowed to be written to the memory cell 305, e.g., to the inverters 310 and 320. The write transistors 330 and 340 can receive a write enable signal from at least one of the synchronous word line decoder 220 or the asynchronous word line decoder 230 that indicates the mode of operation for the memory cell 305. For instance, when the write enable signal is activate or has a high voltage level relative to the characteristics of the write transistors 330 and 340, the write transistors 330 and 340 can be activated or turned on. When the write transistors 330 and 340 are activated, the data on the bit lines BL and B̅L̅ is allowed to propagate to the memory cell 305, or inverters 310 and 320, for storage. When the write enable signal is deactivated or has a low voltage level relative to the characteristics of the write transistors 330 and 340, the write transistors 330 and 340 can be deactivated or turned off, electrically decoupling the bit lines BL and B̅L̅ from the memory cell 305.

### Data Read Operations

The memory cell device 300 includes a digital sensing device 400 capable of reading data from the memory cell 305 when prompted by the memory system 200. After the digital sensing device 400 receives the data stored by the memory cell 305, digital sensing device 400 can generate an output based on the received data for transmission to synchronous bit line SBL and asynchronous bit line ABL. Since the digital sensing device 400 is operated digitally, it consumes less current than its analog sense amplifier predecessor, can respond more quickly when prompted to read data from the memory cell 305, and consumes less area on a chip or integrated circuit.

The digital sensing device 400 is coupled to synchronous word lines SWL- S̅W̅L̅ and to asynchronous word lines AWL- A̅W̅L̅, which control the operation of the digital sensing device 400. For instance, when the synchronous word lines SWL- S̅W̅L̅ are activated by the synchronous word line decoder 220, the digital sensing device 400 generates an output based on the data stored by the memory cell 305, and provides the output to synchronous bit line SBL. Similarly, when the asynchronous word lines AWL- A̅W̅L̅ are activated by the asynchronous word line decoder 230, the digital sensing device 400 generates an output based on the data stored by the memory cell 305, and provides the output to asynchronous bit line ABL.

The digital sensing device 400 can include sensing inverters 400A and 400B that provide load balance on sensing nodes and can pass the data stored by the memory cell 305 in a rail-to-rail voltage range, therefore eliminating the need of a conventional sense amplifier stage. The sensing inverters 400A and 400B can be used synchronously or asynchronous depending on the type of word line decoders incorporated into the memory system 200. In the example embodiments shown in FIG. 3, the memory system 200 includes one synchronous word line decoder 220 and one asynchronous word line decoder 230, and thus the sensing inverter 400A can operate synchronously and the sensing inverter 400B can operate asynchronously. However, if the memory system 200 changes the type of word line decoder, the operation of the sensing inverters 400A and 400B will also change to correspond to the type of word line decoders in the memory system 200.

In the example embodiments shown in FIG. 3, the digital sensing device 400 can include multiple sensing inverters 400A and 400B to receive the data stored by the memory cell 305 and generate an output according to the stored data, and the synchronous word lines SWL- S̅W̅L̅ and asynchronous word lines AWL- A̅W̅L̅, respectively. The sensing inverters 400A and 400B can then provide the output to the synchronous bit line SBL and the asynchronous bit line ABL, respectively. In some embodiments, the sensing inverters 400A and 400B can be tri-buffering inverters.

The sensing inverter 400A can be directly coupled to output of inverter 320, while the sensing inverter 400B can be directly coupled to output of inverter 310. By directly coupling the sensing inverter 400A and the sensing inverter 400B to the respective inverters 310 and 320, the voltage at those nodes is rail-to-rail, allowing for a reduction in a propagation delay to the sensing inverter 400A and the sensing inverter 400B during data read operations. Embodiments of the sensing inverter 400A and the sensing inverter 400B will be described below in greater detail.

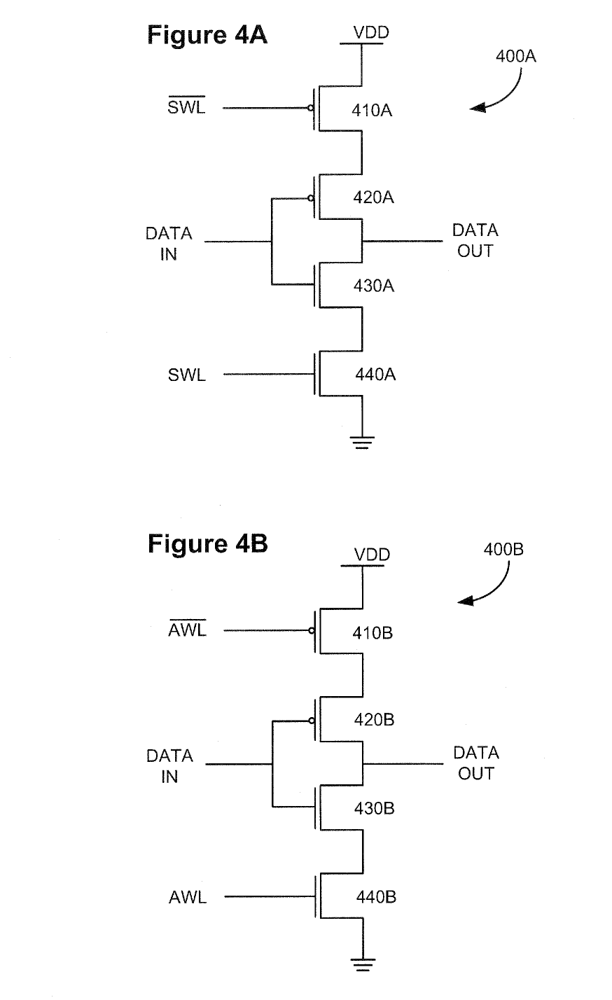

FIGS. 4A and 4B are block diagrams embodiments of the digital sensing inverter 400 shown in FIG. 3. Referring to FIG. 4A, the sensing inverter 400A when activated by the synchronous word lines SWL and S̅W̅L̅, generates an output, or Data Out, that is an inversion of the data stored in the memory cell 305, or Data In. The sensing inverter 400B shown in FIG. 4B operates similarly to the sensing inverter 400A, but is activated by the asynchronous word lines AWL and A̅W̅L̅, as opposed to the synchronous word lines SWL and S̅W̅L̅.

The sensing inverter 400A includes a plurality of transistors 410A-440A. The transistor 410A is coupled between a supply voltage VDD and transistor 420A, and is activated according to a synchronous word line SWL. The transistor 440A is coupled between a ground and transistor 430A, and is activated according to a synchronous word line S̅W̅L̅. The transistors 420A and 430A are coupled to each other and are activated according to data stored in the memory cell 305. The node that couples the transistors 420A and 430A provides an output to the synchronous bit line SBL.

When the transistors 410A and 440A are not activated by the synchronous word lines SWL and S̅W̅L̅, there is a high impedance condition in the sensing device 400A, thus providing no output to the synchronous bit line SBL. When the transistors 410A and 440A are activated by the synchronous word lines SWL and S̅W̅L̅, the data stored in the memory cell 305 or Data In, controls the output of the sensing inverter 400A, or Data Out. For instance, when a high voltage level or “1” is stored in the memory cell 305, the transistor 430A will be activated and transistor 420A will not be activated, which draws the voltage level of Data Out to a low level or “0”. Conversely, when a low voltage level or “0” is stored in the memory cell 305, the transistor 420A will be activated and transistor 430A will not be activated, which draws the voltage level of Data Out to a high level or “1”. Thus when activated by the synchronous word lines SWL and S̅W̅L̅, the sensing inverter 400A generates an output, or Data Out, that is an inversion of the data stored in the memory cell 305, or Data In.

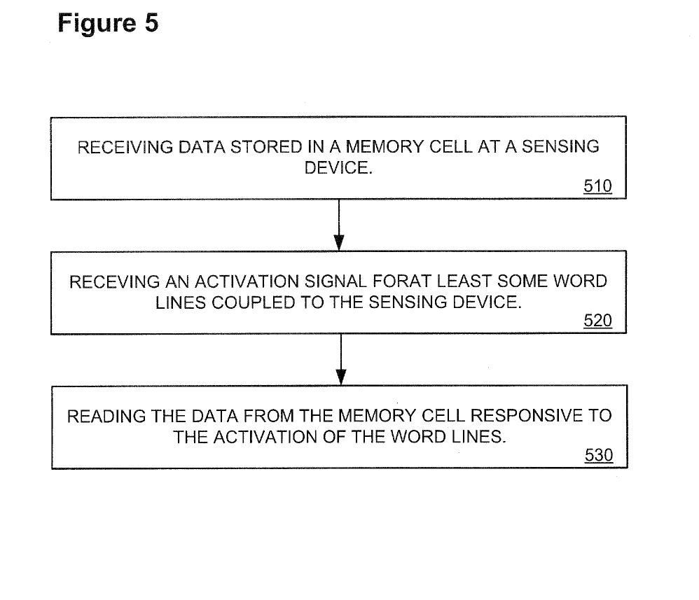

FIG. 5 is an example flowchart of the digital sensing device 400 shown in FIG. 3. Referring to FIG. 5, at a block 510, the digital sensing device 400 receives data stored in the memory cell 305. The digital sensing device 400 can be directly coupled to the memory cell 305, i.e., by sharing a node that stores data in the memory cell, and thus receive a voltage associated with the stored data with minimal transmission delay. In some embodiments, the digital sensing device 400 can include the sensing device 400A which is directly coupled to output of inverter 320 in the memory cell 305 to receive the stored data. The digital sensing device 400 can include the sensing inverter 400B which is directly coupled to output of inverter 310 in the memory cell 305 to receive the stored data.

At a next block 520, the digital sensing device 400 receiving an activation signal corresponding to word lines coupled to the digital sensing device 400. The digital sensing device 400 can couple to multiple word lines, such as synchronous word lines SWL and S̅W̅L̅ and asynchronous word lines AWL and A̅W̅L̅. The memory system 200 can include multiple decoders 220 and 230 to activate the synchronous word lines SWL and S̅W̅L̅ and asynchronous word lines AWL and A̅W̅L̅, respectively, which are provided to the digital sensing device 400.

In some embodiments, the digital sensing device 400 includes the sensing device 400A that couples to the synchronous word lines SWL and S̅W̅L̅ and receives the activation signal when provided by the decoder 220. The digital sensing device 400 includes the sensing device 400B that couples to the asynchronous word lines AWL and A̅W̅L̅ and receives the activation signal when provided by the decoder 230.

At a next block 530, the digital sensing device 400 reads the data from the memory cell responsive to the activation of the word lines. When these word lines are activated, the digital sensing device 400 can generate an output, or Data Out, that is based on the data stored in the memory cell 305. The digital sensing device 400 then provides the output to corresponding read bit lines, or synchronous bit line SBL or the asynchronous bit line ABL, thus reading the stored data from the memory cell 305.

In some embodiments, when activated, the synchronous word lines SWL and S̅W̅L̅ can activate at least a portion of the sensing device 400A to generate an output based on the data stored in the memory cell 305 and provide the output to at least one of the synchronous bit line SBL. Similarly, the asynchronous word lines AWL and A̅W̅L̅, when activated, can enable the sensing device 400B to generate an output based on the data stored in the memory cell 305 and provide the output to at least one of the asynchronous bit line ABL. Thus, data stored in the memory cell 305 can be read by the digital sensing device 400 and provided to corresponding read bit lines responsive to the activation of the corresponding word lines.

One of skill in the art will recognize that the concepts taught herein can be tailored to a particular application in many other advantageous ways. In particular, those skilled in the art will recognize that the illustrated embodiments are but one of many alternative implementations that will become apparent upon reading this disclosure.

The preceding embodiments are exemplary. Although the specification may refer to “an”, “one”, “another”, or “some” embodiment(s) in several locations, this does not necessarily mean that each such reference is to the same embodiment(s), or that the feature only applies to a single embodiment.

1. A device comprising:
a memory cell to store data received over one or more write bit lines; and
a sensing inversion device coupled to the memory cell and word lines, the sensing inversion device to read data stored by the memory cell and provide the read data to one or more read bit lines when the word lines are activated for read operations.

2. The device of claim 1 where the sensing inversion device is operable to receive the stored data directly from the memory cell, generate an output based on the data from the memory cell, and provide the generated output to one or more of the read bit lines.

3. The device of claim 1 where the sensing inversion device includes a synchronous sensing inverter coupled to a pair of synchronous word lines, the synchronous sensing inverter to read data from the memory cell when at least one of the synchronous word lines is activated.

4. The device of claim 3 where the sensing inversion device includes an asynchronous sensing inverter coupled to a pair of asynchronous word lines, the asynchronous sensing inverter to read data from the memory cell when at least one of the asynchronous word lines is activated.

5. The device of claim 1 where the memory cell is a static random access memory cell including a pair of inverters to store the data.

6. The device of claim 1 including at least one data write driver to provide data to be written to the memory cell over at least one of the write bit lines, the memory cell to store the data provided by the data write driver according to a write enable signal.

7. The device of claim 6 including multiple write transistors to enable the data from the data write drivers to propagate to the memory cell when activated by the write enable signal.

8. A method comprising:
receiving data stored in a memory cell at a digital sensing device;
receiving at least one activation signal corresponding to word lines coupled to the digital sensing device; and
reading the data from the memory cell responsive to the activation of the word lines.

9. The method of claim 8 where reading data from the memory cell includes providing the data to one or more read bit lines responsive to the activation of the word lines.

10. The method of claim 9 where reading data from the memory cell includes generating a synchronous output based on the data from the memory cell when one or more synchronous word lines are activated.

11. The method of claim 10 where reading data from the memory cell includes generating an asynchronous output based on the data from the memory cell when one or more asynchronous word lines are activated.

12. The method of claim 8 where the memory cell is a static random access memory cell including a pair of inverters to store the data.

13. The method of claim 8 includes writing data to the memory cell when a write enable signal is activated.

14. The method of claim 13 where the reading of data from the memory cell and the writing of data to the memory cell are performed over different bit lines

15. A system comprising:
at least one word line decoder to select word lines to activate; and
a memory cell array having a plurality of memory cell devices to store data received through one or more write bit lines, the memory cell devices including sensing inversion devices to read data stored in the corresponding memory cell devices according to the activation of the selected word lines and provide an output associated with the read data to one or more read bit lines.

16. The device of claim 15 where the word line decoder is operable to provide a write enable signal to the memory cell corresponding to the activation of the selected word lines, the write enable signal to indicate whether data is to be written to or read from the memory cell.

17. The device of claim 15 including a synchronous word line decoder to select one or more synchronous word lines to activate, at least one of the sensing inversion devices to read data stored in the corresponding memory cells according to the activation of the synchronous word lines.

18. The device of claim 17 where one or more of the sensing inversion devices include synchronous sensing inverters to generate a synchronous output based on data stored in the corresponding memory cells and to provide the synchronous output to one or more synchronous bit lines.

19. The device of claim 17 including an asynchronous word line decoder to select one or more asynchronous word lines to activate, at least one of the sensing inversion devices to read data stored in the corresponding memory cells according to the activation of the asynchronous word lines.

20. The device of claim 19 where one or more of the sensing inversion devices include asynchronous sensing inverters to generate an asynchronous output based on data stored in the corresponding memory cells and to provide the asynchronous output to one or more asynchronous bit lines.
